(19) United States
(12) Patent Application Publication
(10) Pub. No.: US 2013/0087185 A1
(43) Pub. Date: Apr. 11, 2013

(54) SILICON RIBBON, SPHERICAL SILICON, SOLAR CELL, SOLAR CELL MODULE, METHOD FOR MANUFACTURING SILICON RIBBON, AND METHOD FOR MANUFACTURING SPHERICAL SILICON

(71) Applicant: Ryuichi Oishi, Osaka-shi (JP)

(72) Inventor: Ryuichi Oishi, Osaka-shi (JP)

(73) Assignee: SHARP KABUSHIKI KAISHA, Osaka-shi, Osaka (JP)

(21) Appl. No.: 13/704,455

(22) PCT Filed: Jun. 10, 2011
(86) PCT No.: PCT/JP2011/063340

§ 371 Date: Dec. 14, 2012

(30) Foreign Application Priority Data
Jun. 15, 2010 (JP) 2010-136087

(51) Int. Cl. H01L 31/18; H01L 31/05

(52) U.S. Cl. CPC H01L 31/182; H01L 31/0512
USPC 136/249; 438/57

(57) ABSTRACT

Disclosed are a silicon ribbon and spherical silicon directly fabricated from a melt, wherein a nitrogen concentration of the silicon ribbon and the spherical silicon is 5×10¹⁵ atoms/cm³ or higher and 5×10¹⁷ atoms/cm³ or lower. Also disclosed are a method for manufacturing the silicon ribbon, a method for manufacturing the spherical silicon, a solar cell and a solar cell module fabricated using the silicon ribbon, and a solar cell and a solar cell module fabricated using the spherical silicon.

### TECHNICAL FIELD

The present invention relates to a silicon ribbon, spherical silicon, a solar cell, a solar cell module, a method for manufacturing the silicon ribbon, and a method for manufacturing the spherical silicon.

### BACKGROUND ART

Recently, for environmental problems on a global scale, renewable energy has attracted attention, and among the renewable energy, a solar battery has particularly attracted a great deal of attention. In particular, a silicon crystal type solar battery has been a mainstream of the solar battery.

The most typical silicon crystal type solar battery is a p-n junction type solar cell in which an n-type layer is formed on a surface of a p-type silicon crystal substrate doped with a small amount of III-group element such as B (boron) and Ga (gallium), by diffusing a V-group element such as P (phosphorus), for example.

The silicon crystal type solar battery also includes a solar cell in which a p-type 20, layer is formed on a surface of an n-type silicon crystal substrate doped with a small amount of V-group element such as P (phosphorus), a solar cell (including a hetero junction, a pin structure or the like) in which n-type and p-type layers are grown by thin film growth on a p-type or n-type silicon crystal substrate, a solar cell having an MIS (Metal-Insulator-Semiconductor) structure, or the like.

As a method for fabricating a silicon crystal substrate used to fabricate the silicon crystal type solar battery, there are methods (1) to (4) described below, for example:

(1) a method by solidifying a silicon melt to fabricate a large silicon crystal ingot, and slicing the silicon crystal ingot (cast method);

(2) a method by growing a silicon ribbon directly into a shape of a wafer, without bringing a substrate for growth into contact with a silicon melt;

(3) a method by bringing a substrate for growth into contact with a silicon melt and growing a silicon ribbon on the substrate for growth; and

(4) a method by growing spherical silicon by dripping a silicon melt into an inert gas or the like and solidifying the silicon melt during dropping, or putting the silicon melt into a small mold and solidifying the silicon melt.

A growth rate of silicon crystals generally satisfies the relationship of (1)<(2)<(3) and (4).

In addition, in recent years, the reverse leakage current under dark conditions has become an important evaluation item for solar cells. This is because the number of solar cells connected serially in a solar cell module tends to increase in order that the power can be taken out efficiently.

When the number of solar cells connected serially in a solar cell module increases and when only one of them is shaded, the electromotive force of the remaining serially-connected solar cells that are not shaded is applied to the shaded solar cell in the reverse direction. At this time, if the reverse leakage current (leak current) of the shaded solar cell is large, the temperature of a portion where current leakage occurs in the solar cell rises. Therefore, from the viewpoint of ensuring the reliability of the solar cell module, the reverse leakage current under dark conditions of the individual solar cells in the solar cell module has become an important evaluation item in recent years.

In addition, as described in NPL 1 (J. Bauer et al., “INVESTIGATIONS ON DIFFERENT TYPES OF FILAMENTS IN MULTI-CRYSTALLINE SILICON FOR SOLAR CELLS”, 22nd European Photovoltaic Solar Energy Conference, 3-7 September 2007, Milan, Italy, pp. 994-997), it is known that, in multicrystalline silicon fabricated using the cast method described in (1) above, nitrogen introduced as an impurity is responsible for the increase in the reverse leakage current (refer to “2.1 SiC filaments” in the left column on p. 994 of NPL 1).

When the multicrystalline silicon is fabricated using the cast method, carbon and nitrogen are introduced as impurities into a raw material or a silicon melt during crystal growth. The carbon impurity introduced into the silicon melt is then precipitated as a silicon carbide (SiC) filament, and the nitrogen impurity is taken into the silicon carbide filament as an n-type impurity and develops conductivity (refer to “2.1 SiC filaments” in the left column on p. 994 of NPL 1). The conductive multicrystalline silicon carbide filament causes short circuit between an n+ emitter layer and a back surface field (BSF) layer (p+ layer) of the solar cell (refer to “1 INTRODUCTION” in the left column on p. 994 of NPL 1).

Taking a very typical solar cell having an n+/p/p+ structure as an example, the causes of the reverse leakage current generated in the solar cell include the following (a) to (d):

(a) insufficient junction separation at a side surface of the solar cell;

(b) penetration, into a p layer, of an n electrode on a light receiving surface of the solar cell;

(c) seepage or penetration of a dopant such as phosphorus or aluminum into a cracked part of a silicon crystal substrate; and

(d) a defect level or impurity level at a p-n junction.

Furthermore, the solar battery is expected to be clean energy and an amount of its introduction is steadily increasing. However, cost performance must be further improved in order that the solar cell will achieve more widespread use and serve for global environmental preservation in the future.

### CITATION LIST

### Non Patent Literature

NPL 1: J. Bauer et al., “INVESTIGATIONS ON DIFFERENT TYPES OF FILAMENTS IN MULTI-CRYSTALLINE SILICON FOR SOLAR CELLS”, 22nd European Photovoltaic Solar Energy Conference, 3-7 Sep. 2007, Milan, Italy, pp. 994-997

### SUMMARY OF INVENTION

### Technical Problem

In light of the aforementioned circumstances, an object of the present invention is to provide a silicon ribbon and spherical silicon in which the reverse leakage current of a solar cell can be reduced and the manufacturing cost can be reduced with enhanced yield of a solar cell and a solar cell module. The object of the present invention is to further provide a solar cell and a solar cell module fabricated using the silicon ribbon, a solar cell and a solar cell module fabricated using the spherical silicon, a method for manufacturing the silicon ribbon, and a method for manufacturing the spherical silicon.

### Solution to Problem

The present invention is directed to a silicon ribbon directly fabricated from a melt, wherein a nitrogen concentration of the silicon ribbon is 5×10¹⁵ atoms/cm³ or higher and 5×10¹⁷ atoms/cm³ or lower. “Silicon ribbon directly fabricated from a melt” herein refers to a silicon ribbon fabricated from a melt without taking other shapes such as an ingot.

Preferably, in the silicon ribbon according to the present invention, the nitrogen concentration of the silicon ribbon is 1×10¹⁶ atoms/cm³ or higher and 5×10¹⁶ atoms/cm³ or lower.

The present invention is also directed to a solar cell fabricated using the aforementioned silicon ribbon.

The present invention is also directed to a solar cell module including the aforementioned solar cell.

The present invention is also directed to spherical silicon directly fabricated from a melt, wherein a nitrogen concentration of the spherical silicon is 5×10¹⁵ atoms/cm³ or higher and 5×10¹⁷ atoms/cm³ or lower. “Spherical silicon directly fabricated from a melt” herein refers to spherical silicon fabricated from a melt without taking other shapes such as an ingot.

Preferably, in the spherical silicon according to the present invention, the nitrogen concentration of the spherical silicon is 1×10¹⁶ atoms/cm³ or higher and 5×10¹⁶ atoms/cm³ or lower.

The present invention is also directed to a solar cell fabricated using the aforementioned spherical silicon.

The present invention is also directed to a solar cell module including the aforementioned solar cell.

The present invention is also directed to a method for manufacturing a silicon ribbon, including the steps of: fabricating a nitrogen-containing silicon melt; and growing, from the nitrogen-containing silicon melt, a silicon ribbon having a nitrogen concentration of 5×10¹⁵ atoms/cm³ or higher and 5×10¹⁷ atoms/cm³ or lower.

Preferably, in the method for manufacturing a silicon ribbon according to the present invention, in the step of growing a silicon ribbon, a silicon ribbon having the nitrogen concentration of 1×10¹⁶ atoms/cm³ or higher and 5×10¹⁶ atoms/cm³ or lower is grown.

Preferably, in the method for manufacturing a silicon ribbon according to the present invention, in the step of growing a silicon ribbon, the silicon ribbon is grown on a substrate for growth.

Preferably, in the method for manufacturing a silicon ribbon according to the present invention, in the step of growing a silicon ribbon, a growth rate of the silicon ribbon is 20 μm/sec or higher.

Furthermore, the present invention is directed to a method for manufacturing spherical silicon, including the steps of: fabricating a nitrogen-containing silicon melt; and growing spherical silicon having a nitrogen concentration of 5×10¹⁵ atoms/cm³ or higher and 5×10¹⁷ atoms/cm³ or lower, by dropping the nitrogen-containing silicon melt.

Preferably, in the method for manufacturing spherical silicon according to the present invention, in the step of growing spherical silicon, spherical silicon having the nitrogen concentration of 1×10¹⁶ atoms/cm³ or higher and 5×10¹⁶ atoms/cm³ or lower is grown.

Preferably, in the method for manufacturing spherical silicon according to the present invention, in the step of growing spherical silicon, a growth rate of the spherical silicon is 20 μm/sec or higher.

### Advantageous Effects of Invention

According to the present invention, there can be provided a silicon ribbon and spherical silicon in which the reverse leakage current of a solar cell can be reduced and the manufacturing cost can be reduced with enhanced yield of a solar cell and a solar cell module. There can further be provided a solar cell and a solar cell module fabricated using the silicon ribbon, a solar cell and a solar cell module fabricated using the spherical silicon, a method for manufacturing the silicon ribbon, and a method for manufacturing the spherical silicon.

### BRIEF DESCRIPTION OF DRAWINGS

FIG. 1 is a schematic configuration diagram of an example of a silicon ribbon growth apparatus.

FIG. 2 is a schematic configuration diagram of another example of the silicon ribbon growth apparatus.

FIGS. 3(a) to 3(i) are schematic cross-sectional views illustrating an example of a method for fabricating a solar cell using a silicon ribbon according to the present invention.

FIG. 4 is a schematic cross-sectional view of an example of a solar cell module according to the present invention.

FIG. 5 is a schematic configuration diagram of an example of a spherical silicon growth apparatus.

FIG. 6 is a schematic cross-sectional view of an example of a solar cell fabricated using spherical silicon according to the present invention.

FIG. 7 is a schematic configuration diagram of an example of a cast silicon growth apparatus in Comparative Example 1.

FIG. 8 is a graph showing a relationship between a nitrogen concentration (atoms/cm³) of silicon ribbons in solar cells in Example 1 and a reverse leakage current (A) under dark conditions.

FIG. 9 is a graph showing a relationship between a nitrogen concentration (atoms/cm³) of silicon ribbons in solar cells in Example 2 and a reverse leakage current (A) under dark conditions.

FIG. 10 is a graph showing a relationship between a nitrogen concentration (atoms/cm³) of silicon ribbons in solar cells in Example 3 and a reverse leakage current (A) under dark conditions.

FIG. 11 is a graph showing a relationship between a nitrogen concentration (atoms/cm³) of silicon ribbons in solar cells in Comparative Example 1 and a reverse leakage current (A) under dark conditions.

### DESCRIPTION OF EMBODIMENTS

Embodiments of the present invention will be described hereinafter. In the drawings of the present invention, the same reference characters indicate the same or corresponding portions.

<Silicon Ribbon>

A silicon ribbon according to the present invention is a silicon ribbon directly fabricated from a melt, wherein a nitrogen concentration of the silicon ribbon is 5×10¹⁵ atoms/cm³ or higher and 5×10¹⁷ atoms/cm³ or lower. This is based on the following findings obtained as a result of earnest study by the inventor of the present invention: the reverse leakage current can be reduced of a solar cell fabricated using the silicon ribbon having a nitrogen concentration of 5×10¹⁵ atoms/cm³ or higher and 5×10¹⁷ atoms/cm³ or lower. Although a mechanism for allowing reduction in the reverse leakage current is not necessarily clear, it is conceivable that the reverse leakage current can be reduced because nitrogen passivates a defect level near a p-n junction formed in the silicon ribbon when the nitrogen concentration is around 5×10¹⁵ atoms/cm³ or higher and 5×10¹⁷ atoms/cm³ or lower. When the nitrogen concentration of the silicon ribbon exceeds 5×10¹⁷ atoms/cm³, the defect level caused by the high concentration of nitrogen appears in the silicon ribbon, which is considered to increase the reverse leakage current.

The nitrogen concentration of the silicon ribbon according to the present invention is preferably 1×10¹⁶ atoms/cm³ or higher and 5×10¹⁶ atoms/cm³ or lower. When a solar cell is fabricated using the silicon ribbon having a nitrogen concentration of 1×10¹⁶ atoms/cm³ or higher and 5×10¹⁶ atoms/cm³ or lower, the reverse leakage current in the solar cell tends to be further reduced.

It should be noted that the nitrogen concentration of the silicon ribbon according to the present invention corresponds to a value obtained by dividing the total number of nitrogen atoms in the silicon ribbon by the volume of the silicon ribbon. The nitrogen concentration can be calculated using, for example, SIMS (secondary ion mass spectrometry), CPAA (charged particle activation analysis) and the like.

<Method for Manufacturing Silicon Ribbon>

The silicon ribbon according to the present invention is characterized in that the silicon ribbon is directly fabricated from the melt. This is probably because a growth rate is high, the nitrogen segregation effect does not work very well and the behavior of nitrogen in crystals is different, as compared with the cast method that requires solidifying the melt to fabricate the crystal silicon ingot. It is conceivable that a silicon crystal substrate fabricated using the cast method also includes nitrogen which behaves similarly to nitrogen in the silicon ribbon according to the present invention. However, such nitrogen is often present at a position described in NPL 1 (in SiC). Therefore, it is conceivable that the influence of nitrogen on reduction in the reverse leakage current is different.

A method for manufacturing a silicon ribbon according to the present invention includes the steps of: (i) fabricating a nitrogen-containing silicon melt; and (ii) growing a silicon ribbon.

(i) Step of Fabricating Nitrogen-Containing Silicon Melt

In the step of fabricating a nitrogen-containing silicon melt, the nitrogen-containing silicon melt can be fabricated, for example, by causing nitrogen to be contained in a silicon melt fabricated using a conventionally known method. A method for introducing a nitrogen-containing gas into a chamber that houses the silicon melt, a method for injecting silicon nitride into the silicon melt, or the like can be used, for example, as a method for causing nitrogen to be contained in a silicon melt. A concentration of nitrogen in the nitrogen-containing silicon melt can be appropriately adjusted by adjusting, for example, a flow rate and an introduction time period of the nitrogen gas introduced into the chamber that houses the silicon melt, or an amount of the silicon nitride injected into the silicon melt. Therefore, in this step, the concentration of nitrogen in the silicon melt is adjusted such that a silicon ribbon grown in the step (ii) below has a nitrogen concentration of 5×10¹⁵ atoms/cm³ or higher and 5×10¹⁷ atoms/cm³ or lower, and preferably 1×10¹⁶ atoms/cm³ or higher and 5×10¹⁶ atoms/cm³ or lower. The nitrogen-containing silicon melt may contain, for example, a III-group element such as B (boron), Al (aluminum) and Ga (gallium), a V-group element such as P (phosphorus), As (arsenic) and Sb (antimony), or the like such that the silicon ribbon has a porn conductivity type.

(ii) Step of Growing Silicon Ribbon

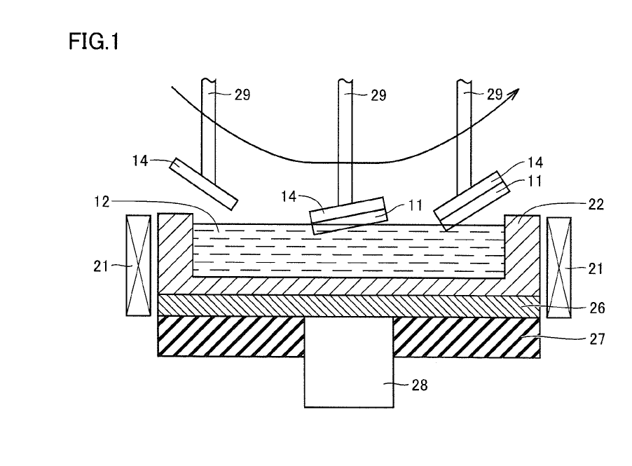

The silicon ribbon is grown from the nitrogen-containing silicon melt fabricated in the step (i) above, and the silicon ribbon according to the present invention is directly fabricated from the nitrogen-containing silicon melt. FIG. 1 shows a schematic configuration diagram of an example of a silicon ribbon growth apparatus.

The silicon ribbon growth apparatus shown in FIG. 1 has a crucible platform 26, a crucible 22 attached to crucible platform 26, a crucible elevating platform 28 attached to crucible platform 26 on the side opposite to crucible 22, a heat insulator 27 attached on a lower surface of crucible platform 26, a heating heater 21 for heating crucible 22, and a shaft 29 provided above crucible 22. The silicon ribbon growth apparatus shown in FIG. 1 is preferably placed within the chamber such that evacuation can be performed. In addition, although not shown, the silicon ribbon growth apparatus shown in FIG. 1 may have, for example, a device for moving shaft 29 in a direction shown by an arrow in FIG. 1, a device for controlling heating heater 21, a device for additionally injecting the nitrogen-containing silicon melt into crucible 22, or the like.

The step of growing the silicon ribbon using the silicon ribbon growth apparatus shown in FIG. 1 is performed as described below, for example. First, a nitrogen-containing silicon melt 12 fabricated in the step (i) above is housed within crucible 22 and the temperature of nitrogen-containing silicon melt 12 in crucible 22 is kept at, for example, approximately 1420° C. to 1440° C. by heating heater 21.

Next, a substrate 14 for silicon ribbon growth is attached to a tip of shaft 29 and shaft 29 is moved in the direction shown by the arrow in FIG. 1. As a result, a surface of substrate 14 for silicon ribbon growth is immersed into nitrogen-containing silicon melt 12 in crucible 22, such that substrate 14 for silicon ribbon growth comes into contact with nitrogen-containing silicon melt 12. Substrate 14 for silicon ribbon growth is preferably made of a material having good heat conductivity and/or a material having excellent heat resistance, and such a material includes, for example, graphite, silicon carbide, boron nitride and the like.

A time period during which the surface of substrate 14 for silicon ribbon growth is immersed into nitrogen-containing silicon melt 12 may be set at an appropriate time period in accordance with the desired thickness of a silicon ribbon 11. The immersion time period for obtaining silicon ribbon 11 having a thickness of, for example, 300 μm is about approximately 3 to 4 seconds.

As described above, silicon ribbon 11 having a nitrogen concentration of 5×10¹⁵ atoms/cm³ or higher and 5×10¹⁷ atoms/cm³ or lower, and preferably 1×10¹⁶ atoms/cm³ or higher and 5×10¹⁶ atoms/cm³ or lower is grown on the surface of substrate 14 for silicon ribbon growth.

A growth rate of silicon ribbon 11 is preferably 20 μm/sec or higher. When the growth rate of silicon ribbon 11 is 20 μm/sec or higher, silicon ribbon 11 can efficiently take in nitrogen that can effectively reduce the reverse leakage current, and silicon ribbon 11 that has taken in such nitrogen can be efficiently manufactured in a stable manner. Therefore, silicon ribbon 11 in which the reverse leakage current in a solar cell can be effectively reduced tends to be manufactured with excellent manufacturing yield and at low cost. It should be noted that the growth rate of silicon ribbon 11 herein refers to the growth rate of silicon ribbon 11 in a direction vertical to the surface of substrate 14 for silicon ribbon growth.

Thereafter, by further moving shaft 29 in the direction shown by the arrow in FIG. 1, the surface of substrate 14 for silicon ribbon growth is pulled away from nitrogen-containing silicon melt 12, and then, silicon ribbon 11 is removed from substrate 14 for silicon ribbon growth. Silicon ribbon 11 according to the present invention can be thus fabricated.

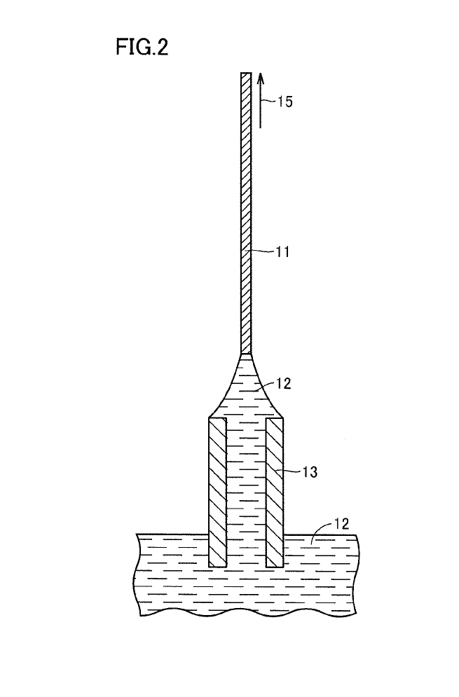

An example of the method for fabricating silicon ribbon 11 according to the present invention using substrate 14 for silicon ribbon growth has been described above. An example of a method for fabricating silicon ribbon 11 according to the present invention without using substrate 14 for silicon ribbon growth will be described hereinafter with reference to FIG. 2 showing a schematic configuration diagram of another example of the silicon ribbon growth apparatus.

First, as shown in FIG. 2, two plate-like bodies 13 are immersed, with a spacing therebetween, into nitrogen-containing silicon melt 12 fabricated in the step (i) above. A graphite plate or the like can, for example, be used as plate-like body 13.

Next, nitrogen-containing silicon melt 12 is pulled up from between two plate-like bodies 13 in a direction shown by an arrow 15 and nitrogen-containing silicon melt 12 is cooled, thereby growing silicon ribbon 11 according to the present invention that has a nitrogen concentration of 5×10¹⁵ atoms/cm³ or higher and 5×10¹⁷ atoms/cm³ or lower, and preferably 1×10¹⁶ atoms/cm³ or higher and 5×10¹⁶ atoms/cm³ or lower.

In principle, the effect of reducing the reverse leakage current due to nitrogen in silicon ribbon 11 according to the present invention has a positive correlation with the growth rate of the silicon ribbon. The method for manufacturing the silicon ribbon is broadly divided into two types, i.e., a group in which the substrate for silicon ribbon growth is not used and a group in which the substrate for silicon ribbon growth is used to grow the silicon ribbon on the substrate for silicon ribbon growth. In the latter group, heat removal from the substrate for silicon ribbon growth is possible, and thus, the growth rate of the silicon ribbon can be increased and the effect of reducing the reverse leakage current in the silicon ribbon due to nitrogen is increased, as compared with the former group.

The group in which the substrate for silicon ribbon growth is not used includes, for example, EFG (registered trademark) (Edge-Defined Film-fed Growth), String Ribbon (registered trademark) or the like. The group in which the substrate for silicon ribbon growth is used to grow the silicon ribbon on the substrate for silicon ribbon growth includes, for example, an RGS (Ribbon Growth on Substrate) method, an RST (Ribbon on Sacrificial Carbon Template) method, a method for bringing the substrate for silicon ribbon growth into contact with the melt to grow the silicon ribbon on the substrate for silicon ribbon growth like the aforementioned method, or the like.

<Solar Cell and Solar Cell Module Using Silicon Ribbon>

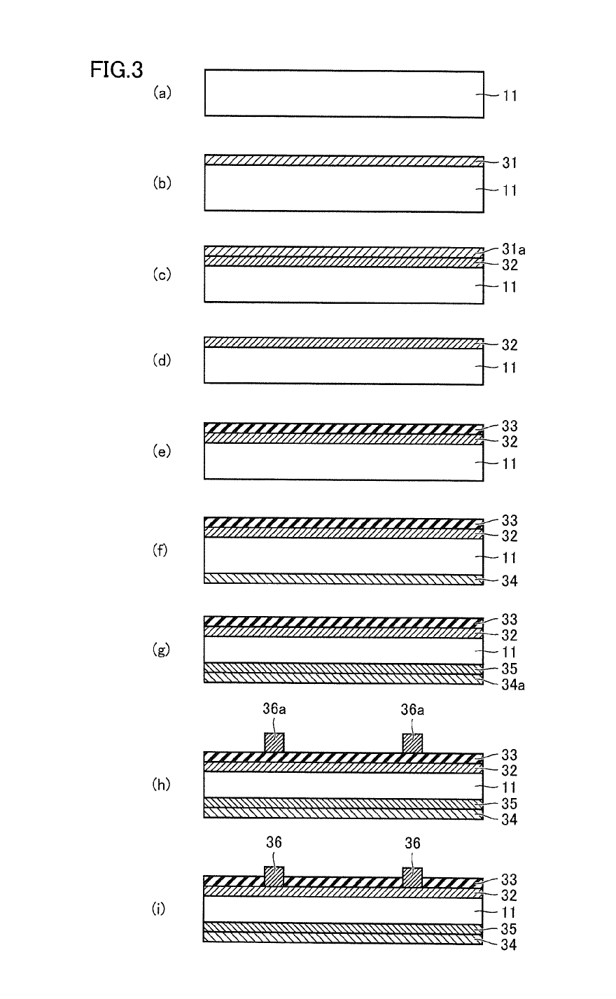

An example of a method for fabricating a solar cell using the silicon ribbon according to the present invention will be described hereinafter with reference to schematic cross-sectional views in FIGS. 3(a) to 3(i).

First, as shown in FIG. 3(a), p-type silicon ribbon 11 is prepared. By texture etching of this silicon ribbon 11, a texture structure (not shown) is formed on a surface of silicon ribbon 11.

Next, as shown in FIG. 3(b), a PSG (phosphorus silicate glass) liquid 31 is applied to the surface of silicon ribbon 11 that will serve as a light receiving surface of the solar cell.

Next, silicon ribbon 11 to which PSG liquid 31 has been applied is heated to diffuse phosphorus from PSG liquid 31 into silicon ribbon 11. As a result, as shown in FIG. 3(c), an n+ layer 32 is formed on the surface of silicon ribbon 11 that will serve as the light receiving surface of the solar cell. At this time, a PSG film 31a is formed on n+ layer 32. Thereafter, as shown in FIG. 3(d), PSG film 31a formed at the time of the diffusion of phosphorus is removed.

Next, as shown in FIG. 3(e), an antireflective film 33 such as, for example, a silicon nitride film is formed on n+ layer 32 of silicon ribbon 11.

Next, as shown in FIG. 3(f), an aluminum paste 34 is applied to a surface (rear surface) of silicon ribbon 11 that will serve as a rear surface of the solar cell. Then, silicon ribbon 11 to which aluminum paste 34 has been applied is baked to diffuse aluminum from aluminum paste 34 into the rear surface of silicon ribbon 11. As a result, as shown in FIG. 3(g), an aluminum electrode 34a and a p+ layer 35 are simultaneously formed on the rear surface of silicon ribbon 11.

Next, as shown in FIG. 3(h), a silver paste 36a is applied onto a surface of antireflective film 33, and thereafter, is baked. As a result, as shown in FIG. 3(i), a silver electrode 36 electrically connecting with n+ layer 32 is formed. Thereafter, a solder is applied to silver electrode 36. An example of the solar cell is thus fabricated using the silicon ribbon according to the present invention.

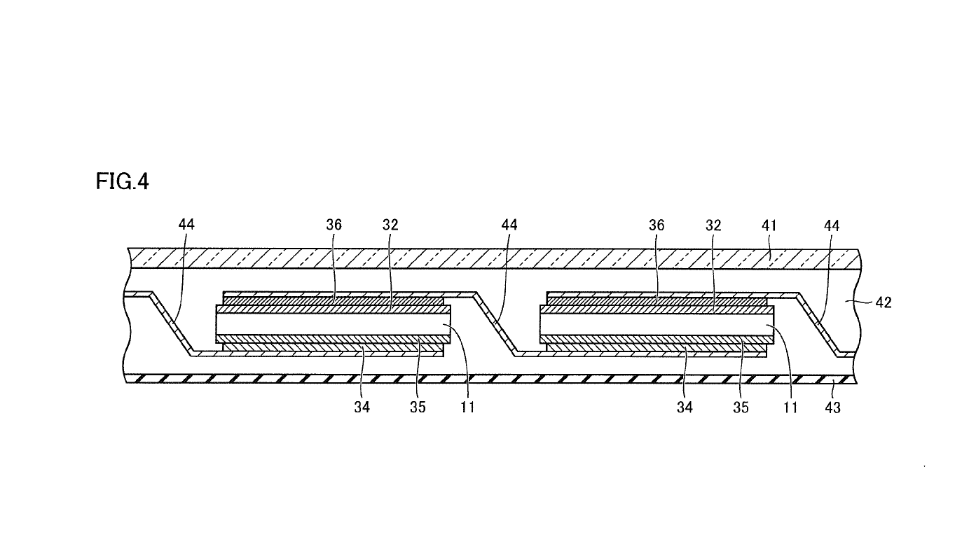

FIG. 4 shows a schematic cross-sectional view of an example of a solar cell module including the solar cell fabricated as described above. The solar cell module is formed by serially and electrically connecting a plurality of solar cells fabricated using the silicon ribbon according to the present invention.

Specifically, silver electrode 36 on the light receiving surface side of one solar cell and aluminum electrode 34a on the rear surface side of the other solar cell, which are arranged adjacent to each other, are electrically connected by a conductive member 44 called “interconnector”, and thereby these solar cells are electrically and serially connected. A solar cell string is thus configured.

Then, the aforementioned solar cell string is sealed in a sealant 42 placed between a transparent substrate 41 and a protective sheet 43. The solar cell module is thus fabricated. A glass substrate or the like can, for example, be used as transparent substrate 41. A PET (polyethylene terephthalate) film or the like can, for example, be used as protective sheet 43. Furthermore, a transparent resin such as EVA (ethylene vinyl acetate) can, for example, be used as sealant 42.

Since the solar cell and the solar cell module fabricated as described above are fabricated using silicon ribbon 11 according to the present invention that has a nitrogen concentration of 5×10¹⁵ atoms/cm³ or higher and 5×10¹⁷ atoms/cm³ or lower, and preferably 1×10¹⁶ atoms/cm³ or higher and 5×10¹⁶ atoms/cm³ or lower, the reverse leakage current in the solar cell is reduced. Therefore, a rate of occurrence of defective products caused by large reverse leakage current is low, and thus, the solar cell and the solar cell module having excellent properties can be manufactured with high manufacturing yield and at low cost.

It should be noted that except for using the silicon ribbon according to the present invention, a conventionally known structure can be used in the solar cell and the solar cell module according to the present invention. For example, a structure in which an n+ layer is formed on the p-type silicon ribbon according to the present invention, a structure in which a p+ layer is formed on the n-type silicon ribbon according to the present invention, a structure including a hetero junction with thin film silicon or the like, the MIS (Metal Insulator Semiconductor) structure and the like may be used. In addition, a method for manufacturing the solar cell is not particularly limited and a conventionally known method can be used.

<Spherical Silicon>

Spherical silicon according to the present invention is spherical silicon directly fabricated from a melt, wherein a nitrogen concentration of the spherical silicon is 5×10¹⁵ atoms/cm³ or higher and 5×10¹⁷ atoms/cm³ or lower. This is based on the following findings obtained as a result of earnest study by the inventor of the present invention: the reverse leakage current can also be reduced in a solar cell fabricated using the spherical silicon having a nitrogen concentration of 5×10¹⁵ atoms/cm³ or higher and 5×10¹⁷ atoms/cm³ or lower. Although a mechanism for allowing reduction in the reverse leakage current is not necessarily clear, it is conceivable that the reverse leakage current can be reduced because nitrogen passivates a defect level near a p-n junction formed in the spherical silicon when the nitrogen concentration is around 5×10¹⁵ atoms/cm³ or higher and 5×10¹⁷ atoms/cm³ or lower. When the nitrogen concentration of the spherical silicon exceeds 5×10¹⁷ atoms/cm³, the defect level caused by the high concentration of nitrogen appears in the spherical silicon, which is considered to increase the reverse leakage current.

The nitrogen concentration of the spherical silicon according to the present invention is preferably 1×10¹⁶ atoms/cm³ or higher and 5×10¹⁶ atoms/cm³ or lower. When a solar cell is fabricated using the spherical silicon having a nitrogen concentration of 1×10¹⁶ atoms/cm³ or higher and 5×10¹⁶ atoms/cm³ or lower, the reverse leakage current in the solar cell tends to be further reduced.

It should be noted that the nitrogen concentration of the spherical silicon according to the present invention corresponds to a value obtained by dividing the total number of nitrogen atoms in the spherical silicon by the volume of the spherical silicon. The nitrogen concentration can be calculated using, for example, SIMS, CPAA and the like.

<Method for Manufacturing Spherical Silicon>

The spherical silicon according to the present invention is characterized in that the spherical silicon is directly fabricated from the melt. This is probably because a growth rate is high, the nitrogen segregation effect does not work very well and the behavior of nitrogen in crystals is different, as compared with the cast method that requires solidifying the melt to fabricate the large crystal silicon ingot. It is conceivable that a silicon crystal substrate fabricated using the cast method also includes nitrogen which behaves similarly to nitrogen in the silicon ribbon according to the present invention. However, such nitrogen is often present at a position described in NPL 1 (in SiC). Therefore, it is conceivable that the influence of nitrogen on reduction in the reverse leakage current is different.

A method for manufacturing spherical silicon according to the present invention includes the steps of: (I) fabricating a nitrogen-containing silicon melt; and (II) growing spherical silicon. Since the step (I) of fabricating a nitrogen-containing silicon melt is similar to the step (i) above, description of the step (I) above will not be repeated here.

(II) Step of Growing Spherical Silicon

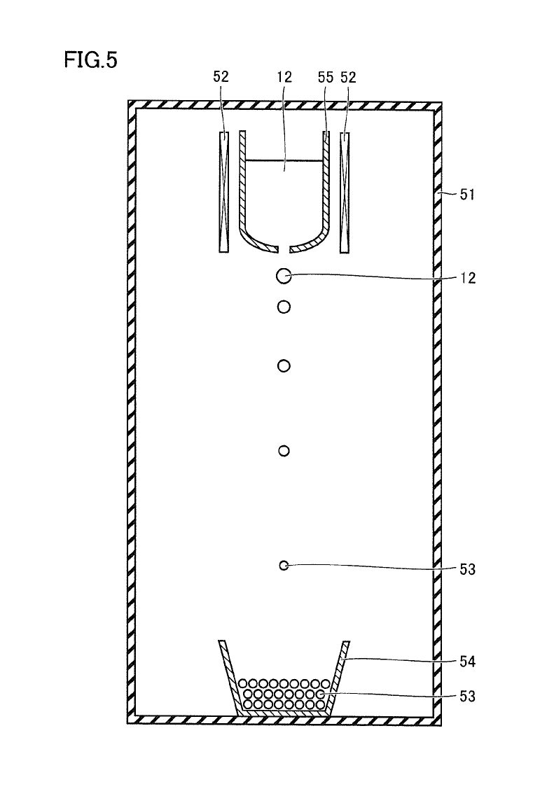

The spherical silicon is grown from the nitrogen-containing silicon melt fabricated in the step (I) above, and the spherical silicon according to the present invention is directly fabricated from the nitrogen-containing silicon melt. FIG. 5 shows a schematic configuration diagram of an example of a spherical silicon growth apparatus.

The spherical silicon growth apparatus shown in FIG. 5 has a chamber 51, a crucible 55 placed in the upper part in chamber 51, a heating heater 52 placed around crucible 55, and a collecting container 54 placed in the lower part in chamber 51.

The step of growing the spherical silicon using the spherical silicon growth apparatus shown in FIG. 5 is performed as described below, for example.

First, the atmosphere in chamber 51 is set at, for example, the argon gas atmosphere and nitrogen-containing silicon melt 12 fabricated in the step (I) above is housed within crucible 55. Then, the temperature of nitrogen-containing silicon melt 12 in crucible 55 is kept at, for example, approximately 1420° C. to 1440° C. by heating heater 52.

Next, nitrogen-containing silicon melt 12 is dropped into chamber 51 from an opening provided in a bottom part of crucible 55. At this time, nitrogen-containing silicon melt 12 is dropped from crucible 55 in a droplet manner. During dropping, droplet-like nitrogen-containing silicon melt 12 is cooled and solidified inside chamber 51. Spherical silicon 53 is thus grown.

Then, spherical silicon 53 grown during dropping is housed within collecting container 54 provided in the lower part in chamber 51. Spherical silicon 53 having a nitrogen concentration of 5×10¹⁵ atoms/cm³ or higher and 5×10¹⁷ atoms/cm³ or lower, and preferably 1×10¹⁶ atoms/cm³ or higher and 5×10¹⁶ atoms/cm³ or lower is thus collected.

A growth rate of spherical silicon 53 is preferably 20 μm/sec or higher, and more preferably 25 μm/sec or higher. When the growth rate of spherical silicon 53 is 20 μm/sec or higher, and particularly 25 μm/sec or higher, spherical silicon 53 can efficiently take in nitrogen that can effectively reduce the reverse leakage current, and spherical silicon 53 that has taken in such nitrogen can be efficiently manufactured in a stable manner. Therefore, spherical silicon 53 in which the reverse leakage current of a solar cell can be effectively reduced tends to be manufactured with excellent manufacturing yield and at low cost. It should be noted that the growth rate of spherical silicon 53 herein refers to a value obtained by dividing a minimum value of a distance between a position of a crystal nucleus and a crystal face (growth front) of a crystal grown from the crystal nucleus by a growth time.

<Solar Cell and Solar Cell Module Using Spherical Silicon>

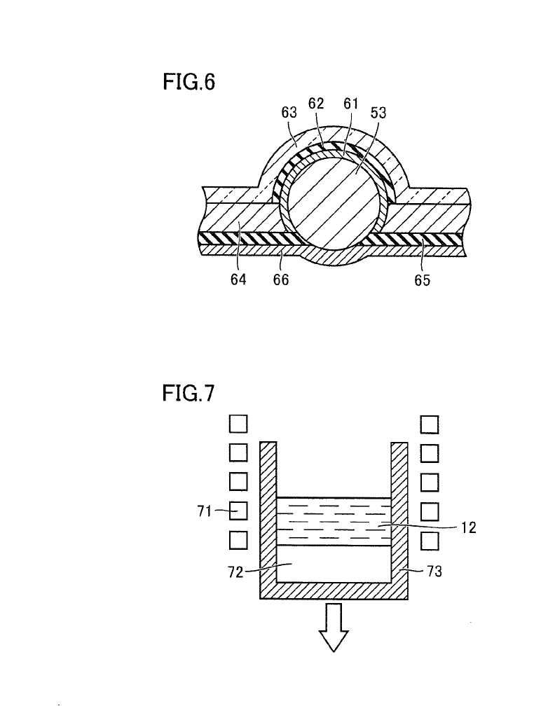

FIG. 6 shows a schematic cross-sectional view of an example of a solar cell fabricated using the spherical silicon according to the present invention. The solar cell shown in FIG. 6 has p-type spherical silicon 53, an n+ layer 61 formed on an outer surface of spherical silicon 53, a conductive sheet 66 that is in contact with p-type spherical silicon 53, a conductive sheet 64 that is in contact with n+ layer 61, an insulating layer 65 placed between conductive sheet 66 and conductive sheet 64, for electrically insulating these, an antireflective film 62 formed on a surface of n+ layer 61, and a transparent protective film 63 covering antireflective film 62 and conductive sheet 64.

An aluminum foil or the like can, for example, be used as conductive sheets 64 and 66. Polyimide or the like can, for example, be used as insulating layer 65. Silicon nitride, titanium oxide or the like can, for example, be used as antireflective film 62. Furthermore, a transparent plastic film or the like can, for example, be used as transparent protective film 63.

The solar cell shown in FIG. 6 can be fabricated as described below, for example. First, a plurality of pieces of p-type spherical silicon 53 are prepared, and an n-type dopant such as, for example, phosphorus is diffused onto the outer surface of these pieces of p-type spherical silicon 53. N+ layer 61 is thus formed.

Next, spherical silicon 53 having n+ layer 61 formed thereon is placed in a hole of perforated conductive sheet 64, and n+ layer 61 exposed from the hole of conductive sheet 64 to the rear surface side is removed by etching.

Next, insulating layer 65 is formed on a rear surface of conductive sheet 64, and thereafter, a part of insulating layer 65 is removed to expose a surface of p-type spherical silicon 53. Then, conductive sheet 66 is placed on the exposed surface of spherical silicon 53.

Next, antireflective film 62 is formed on a surface of n+ layer 61 on the surface side of conductive sheet 64, and thereafter, antireflective film 62 and conductive sheet 64 are covered with transparent protective film 63. An example of the solar cell is thus fabricated using spherical silicon 53 according to the present invention.

Then, a plurality of solar cells fabricated as described above are electrically and serially connected to form a solar cell string, and the aforementioned solar cell string is sealed in the sealant placed between the transparent substrate and the protective sheet. A solar cell module is thus fabricated.

Since the solar cell and the solar cell module fabricated as described above are fabricated using spherical silicon 53 according to the present invention that has a nitrogen concentration of 5×10¹⁵ atoms/cm³ or higher and 5×10¹⁷ atoms/cm³ or lower, and preferably 1×10¹⁶ atoms/cm³ or higher and 5×10¹⁶ atoms/cm³ or lower, the reverse leakage current in the solar cell is reduced. Therefore, a rate of occurrence of defective products caused by large reverse leakage current is low, and thus, the solar cell and the solar cell module having excellent properties can be manufactured with high manufacturing yield and at low cost.

It should be noted that except for using the spherical silicon according to the present invention, a conventionally known structure can be used in the solar cell and the solar cell module according to the present invention. For example, a structure in which an n+ layer is formed on the p-type spherical silicon according to the present invention, a structure in which a p+ layer is formed on the n-type spherical silicon according to the present invention, a structure including a hetero junction with thin film silicon or the like, the MIS (Metal Insulator Semiconductor) structure and the like may be used. In addition, a method for manufacturing the solar cell is not particularly limited and a conventionally known method can be used.

### EXAMPLE

### Silicon Ribbon in Example 1

By performing the steps of: (i) fabricating a nitrogen-containing silicon melt; and (ii) growing a silicon ribbon, using the silicon ribbon growth apparatus shown in FIG. 1, a silicon ribbon was fabricated.

First, 100 kg of a silicon raw material having a boron concentration adjusted to attain a specific resistance of 3 Ω·cm was injected into crucible 22 made of high-purity graphite. Thereafter, the atmosphere in the chamber (not shown) that housed this device was replaced with an argon gas, and the argon gas continued to be constantly flown from the upper part of the chamber into the chamber.

Next, crucible 22 was heated by heating heater 21 to melt the silicon raw material, and thereafter, the temperature was raised to 1550° C. and complete melting of the silicon raw material was confirmed. Thereafter, a small amount of nitrogen gas was introduced into the chamber for 5 hours together with the argon gas. A ratio between a nitrogen gas flow rate and an argon gas flow rate (nitrogen gas flow rate:argon gas flow rate) was about 1:2, and a flow rate of a mixture of the nitrogen gas and the argon gas was 90 L/min.

Thereafter, the introduction of the nitrogen gas into the chamber was stopped and only the argon gas was introduced, and the temperature of crucible 22 was kept at 1420° C. Nitrogen-containing silicon melt 12 was thus stabilized.

Next, under a condition of the immersion time period being 2 seconds, the surface of substrate 14 for silicon ribbon growth made of graphite, which was attached to the tip of shaft 29, was immersed into nitrogen-containing silicon melt 12 obtained as described above, and silicon ribbon 11 was grown on the surface of substrate 14 for silicon ribbon growth. Silicon ribbon 11 thus obtained had a thickness of 280 μm on in-plane average (growth rate: 140 μm/sec).

In addition, in order to check the dependence of silicon ribbon 11 on the nitrogen concentration, fabrication of silicon ribbon 11 was continued until nitrogen-containing silicon melt 12 decreased to 50 kg, and thereafter, 50 kg of the silicon raw material having a boron concentration adjusted to attain a specific resistance of 3 Ω·cm was injected into crucible 22. Then, the silicon raw material was melted without introducing the nitrogen gas into the chamber, and nitrogen-containing silicon melt 12 having a reduced nitrogen concentration was thus fabricated. Then, using the same method and under the same conditions as those in the foregoing, silicon ribbon 11 was grown. By repeating this step, the nitrogen concentration of nitrogen-containing silicon melt 12 was gradually reduced. Thus, nitrogen-containing silicon melts 12 having various nitrogen concentrations were fabricated and silicon ribbons 1 having various nitrogen concentrations were grown.

### Spherical Silicon in Example 2

By performing the steps of: (I) fabricating a nitrogen-containing silicon melt; and (II) growing spherical silicon, using the spherical silicon growth apparatus shown in FIG. 5, spherical silicon was fabricated.

First, 100 kg of a silicon raw material having a boron concentration adjusted to attain a specific resistance of 3 Ω·cm was injected into crucible 55 made of high-purity graphite. Thereafter, the atmosphere in chamber 51 that housed crucible 55 was replaced with an argon gas, and the argon gas continued to be constantly flown from the upper part of chamber 51 into the chamber.

Next, crucible 55 was heated by heating heater 52 to melt the silicon raw material, and thereafter, the temperature was raised to 1550° C. and complete melting of the silicon raw material was confirmed. Thereafter, a small amount of nitrogen gas was introduced into chamber 51 for 5 hours together with the argon gas. A ratio between a nitrogen gas flow rate and an argon gas flow rate (nitrogen gas flow rate:argon gas flow rate) was about 1:2, and a flow rate of a mixture of the nitrogen gas and the argon gas was 90 L/min.

Thereafter, the introduction of the nitrogen gas into chamber 51 was stopped and only the argon gas was introduced, and the temperature of crucible 55 was kept at 1420° C. Nitrogen-containing silicon melt 12 was thus stabilized.

Next, nitrogen-containing silicon melt 12 obtained as described above was dropped about 10 m from the opening provided in the bottom part of crucible 55 toward the lower part of chamber 51. At this time, nitrogen-containing silicon melt 12 was dropped from crucible 55 in a droplet manner. During dropping, droplet-like nitrogen-containing silicon melt 12 was cooled and solidified inside chamber 51. Spherical silicon 53 was thus grown. Then, spherical silicon 53 grown during dropping was housed within collecting container 54 provided in the lower part in chamber 51 and was collected. At this time, a growth rate of spherical silicon 53 was 25 μm/sec.

In addition, in order to check the dependence of spherical silicon 53 on the nitrogen concentration, fabrication of spherical silicon 53 was continued until nitrogen-containing silicon melt 12 decreased to 50 kg, and thereafter, 50 kg of the silicon raw material having a boron concentration adjusted to attain a specific resistance of 3 Ω·cm was injected into crucible 55. Then, the silicon raw material was melted without introducing the nitrogen gas into the chamber, and nitrogen-containing silicon melt 12 having a reduced nitrogen concentration was thus fabricated. Then, using the same method and under the same conditions as those in the foregoing, spherical silicon 53 was grown. By repeating this step, the nitrogen concentration of nitrogen-containing silicon melt 12 was gradually reduced. Thus, nitrogen-containing silicon melts 12 having various nitrogen concentrations were fabricated and pieces of spherical silicon 53 having various nitrogen concentrations were grown.

### Silicon Ribbon in Example 3

By performing the steps of: (i) fabricating a nitrogen-containing silicon melt; and (ii) growing a silicon ribbon, using the silicon ribbon growth apparatus shown in FIG. 2, a silicon ribbon was fabricated.

First, 100 kg of a silicon raw material having a boron concentration adjusted to attain a specific resistance of 3 Ω·cm was injected into a crucible (not shown) made of high-purity graphite. Thereafter, the atmosphere in a chamber (not shown) that housed the crucible was replaced with an argon gas, and the argon gas continued to be constantly flown from the upper part of the chamber (not shown) into the chamber.

Next, the crucible was heated by a heating heater (not shown) to melt the silicon raw material, and thereafter, the temperature was raised to 1550° C. and complete melting of the silicon raw material was confirmed. Thereafter, a small amount of nitrogen gas was introduced into the chamber for 5 hours together with the argon gas. A ratio between a nitrogen gas flow rate and an argon gas flow rate (nitrogen gas flow rate:argon gas flow rate) was about 1:2, and a flow rate of a mixture of the nitrogen gas and the argon gas was 90 L/min.

Thereafter, the introduction of the nitrogen gas into chamber 51 was stopped and only the argon gas was introduced, and the temperature of crucible 55 was kept at 1415° C. Nitrogen-containing silicon melt 12 was thus stabilized.

Next, two plate-like bodies 13 formed of graphite plates were immersed into nitrogen-containing silicon melt 12 with a spacing therebetween.

Next, nitrogen-containing silicon melt 12 was pulled up from between two plate-like bodies 13 in the direction shown by arrow 15 at a pull-up speed of about 85 μ/sec. Silicon ribbon 11 was thus fabricated. At this time, a growth rate of silicon ribbon 11 was 85 μm/sec.

In addition, in order to check the dependence of silicon ribbon 11 on the nitrogen concentration, fabrication of silicon ribbon 11 was continued until nitrogen-containing silicon melt 12 decreased to 50 kg, and thereafter, 50 kg of the silicon raw material having a boron concentration adjusted to attain a specific resistance of 3 Ω·cm was injected into the crucible. Then, the silicon raw material was melted without introducing the nitrogen gas into the chamber, and nitrogen-containing silicon melt 12 having a reduced nitrogen concentration was thus fabricated. Then, using the same method and under the same conditions as those in the foregoing, silicon ribbon 11 was grown. By repeating this step, the nitrogen concentration of nitrogen-containing silicon melt 12 was gradually reduced. Thus, nitrogen-containing silicon melts 12 having various nitrogen concentrations were fabricated and silicon ribbons 1 having various nitrogen concentrations were grown.

### Cast Silicon in Comparative Example 1

By performing the steps of: (A) fabricating a nitrogen-containing silicon melt; and (B) growing cast silicon, using a cast silicon growth apparatus shown in FIG. 7, cast silicon was fabricated.

400 kg of a silicon raw material was charged into a silica crucible 73 (having a rectangular opening whose inner length was 830 mm) having an inner circumferential surface to which a mold release agent made of silicon nitride was applied. Then, silica crucible 73 was heated by a heating heater 71 to melt the silicon raw material, and thereafter, the temperature was raised to 1550° C. and complete melting of the silicon raw material was confirmed. Thereafter, a small amount of nitrogen gas was introduced into a chamber for 5 hours together with the argon gas. A ratio between a nitrogen gas flow rate and an argon gas flow rate (nitrogen gas flow rate:argon gas flow rate) was about 1:2, and a flow rate of a mixture of the nitrogen gas and the argon gas was 90 L/min.

Then, the introduction of the nitrogen gas into the chamber was stopped and only the argon gas was introduced, and the temperature of crucible 73 was kept at 1420° C. for one hour. Nitrogen-containing silicon melt 12 was thus stabilized.

Next, the set temperature of heating heater 71 was decreased at a rate of 0.5° C./hr and the height of silica crucible 73 was lowered at a speed of 8 mm/hr. Cast silicon 72 was thus grown. A growth rate of cast silicon 72 was 3 μm/sec.

In addition, in order to check the dependence of the cast silicon on the nitrogen concentration, fabrication of cast silicon 72 was continued until nitrogen-containing silicon melt 12 decreased to 50 kg, and thereafter, 50 kg of the silicon raw material having a boron concentration adjusted to attain a specific resistance of 3 Ω·cm was injected into the crucible. Then, the silicon raw material was melted without introducing the nitrogen gas into the chamber, and nitrogen-containing silicon melt 12 having a reduced nitrogen concentration was thus fabricated. Then, using the same method and under the same conditions as those in the foregoing, cast silicon 72 was grown. By repeating this step, the nitrogen concentration of nitrogen-containing silicon melt 12 was gradually reduced. Thus, nitrogen-containing silicon melts 12 having various nitrogen concentrations were fabricated and pieces of cast silicon 72 having various nitrogen concentrations were grown.

<Evaluation of Nitrogen Concentration>

About the silicon ribbons fabricated in Example 1, the pieces of spherical silicon fabricated in Example 2, the silicon ribbons fabricated in Example 3, and the pieces of cast silicon fabricated in Comparative Example 1, the nitrogen concentration was measured using the SIMS (secondary ion mass spectrometry). The apparatus and the conditions used to measure the nitrogen concentration were as follows:

apparatus: secondary ion mass spectrometer (manufactured by CAMECA, IMS-6F)

primary ion: Cs⁺, acceleration voltage: 10 kV,

secondary detection ion: ²⁹_{Si}¹⁴N⁻,

secondary extraction voltage: 4.5 kV,

primary current: 100 nA,

primary beam scan region: 80 μm□,

data capture region: 33 μmφ, and

measurement time: 1 sec/point.

Normally, the detection limit is lower when ²⁸Si¹⁴N⁻ is measured as the secondary detection ion. However, ²⁹Si¹⁴N⁻ was used because ³⁰Si¹²C⁻ raised the detection limit (of a nitrogen concentration) when a carbon concentration was high. In addition, a background was checked during measurement from data behavior when the primary beam scan region was small.

### Solar Cell in Example 1

Using the silicon ribbons having various nitrogen concentrations, which were fabricated in Example 1 described above, solar cells including the silicon ribbons having different nitrogen concentrations were fabricated as described below.

First, the p-type silicon ribbon having a thickness of 280 μm, which was fabricated in Example 1, was cut with laser, and p-type silicon ribbon 11 having a square surface of 155 mm×155 mm as shown in FIG. 3(a) was fabricated.

Next, this silicon ribbon 11 was immersed into an aqueous sodium hydroxide solution and anisotropic etching of silicon ribbon 11 was performed. The texture structure (not shown) was thus formed on the surface of silicon ribbon 11.

Next, as shown in FIG. 3(b), PSG liquid 31 was applied by spin coating to the surface of silicon ribbon 11 that will serve as the light receiving surface of the solar cell.

Next, silicon ribbon 11 to which PSG liquid 31 had been applied was placed in a diffusion furnace and was heated to diffuse phosphorus from PSG liquid 31 into silicon ribbon 11. As a result, as shown in FIG. 3(c), n+ layer 32 was formed on the surface of silicon ribbon 11 that will serve as the light receiving surface of the solar cell. Thereafter, silicon ribbon 11 was immersed into hydrofluoric acid. As a result, as shown in FIG. 3(d), PSG film 31a formed at the time of the diffusion of phosphorus was removed.

Next, as shown in FIG. 3(e), antireflective film 33 formed of a silicon nitride film was formed on n+ layer 32 of silicon ribbon 11 using a plasma CVD method.

Next, as shown in FIG. 3(f), aluminum paste 34 was applied by screen printing to the surface (rear surface) of silicon ribbon 11 that will serve as the rear surface of the solar cell. Then, silicon ribbon 11 to which aluminum paste 34 had been applied was baked to diffuse aluminum from aluminum paste 34 into the rear surface of silicon ribbon 11. As a result, as shown in FIG. 3(g), aluminum electrode 34a and p+ layer 35 were simultaneously formed on the rear surface of silicon ribbon 11.

Next, as shown in FIG. 3(h), silver paste 36a was applied by screen printing onto the surface of antireflective film 33 to have a prescribed shape, and thereafter, was baked. As a result, as shown in FIG. 3(i), silver electrode 36 electrically connecting with n+ layer 32 was formed. Thereafter, solder dipping of silver electrode 36 was performed. The solar cell in Example 1 was thus fabricated. If n+ layer 32 comes into contact with aluminum electrode 34a on the rear surface at a marginal portion of silicon ribbon 11, the fill factor (FF) of the solar cell decreases and the conversion efficiency decreases. Therefore, junction separation between n+ layer 32 and aluminum electrode 34a was made.

The aforementioned solar cell fabrication process was performed for the respective silicon ribbons in Example 1 having different nitrogen concentrations. A plurality of solar cells in Example 1 including the silicon ribbons having different nitrogen concentrations were thus fabricated.

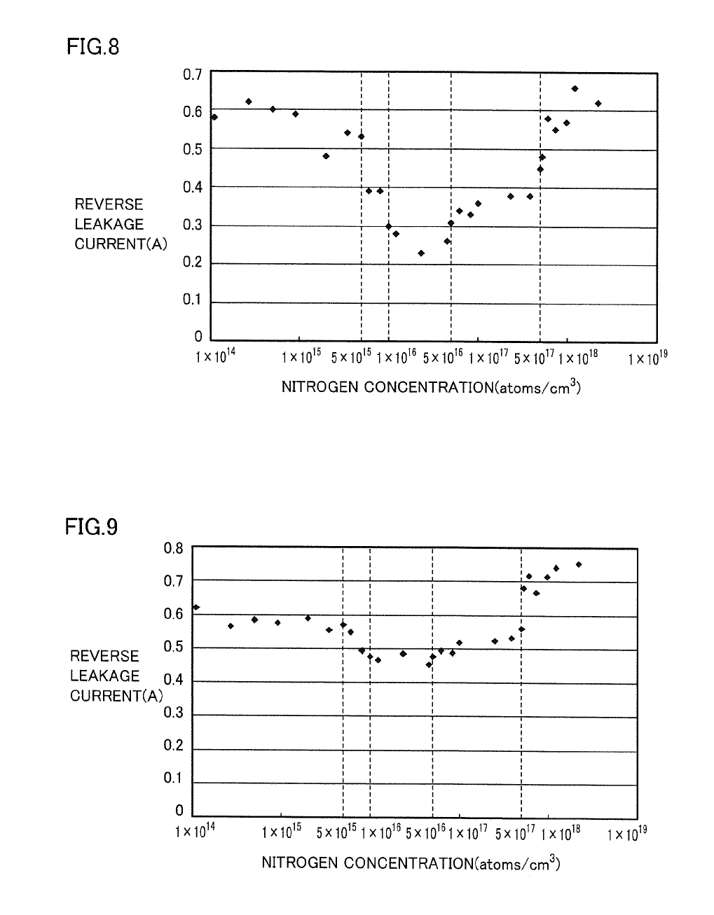

Then, about the respective solar cells in Example 1 fabricated as described above, the reverse leakage current under dark conditions was measured. The result is shown in FIG. 8. In FIG. 8, the horizontal axis indicates the nitrogen concentration (atoms/cm³) of the silicon ribbons in the solar cells in Example 1, and the vertical axis indicates the reverse leakage current (A) under dark conditions. The reverse leakage current under dark conditions was obtained by applying a positive voltage of +10 V to the silver electrode 36 side of the solar cell and measuring a current flowing through the solar cell, without irradiating the solar cell in Example 1 with light.

As shown in FIG. 8, the following was recognized: when the nitrogen concentration of the silicon ribbon is in the range of 5×10¹⁵ atoms/cm³ or higher and 5×10¹⁷ atoms/cm³ or lower, the reverse leakage current under dark conditions tends to be small, and when the nitrogen concentration of the silicon ribbon is in the range of 1×10¹⁶ atoms/cm³ or higher and 5×10¹⁶ atoms/cm³ or lower, the reverse leakage current under dark conditions tends to be particularly small.

It should be noted that the nitrogen concentration indicated by the horizontal axis in FIG. 8 is a result of measurement with the aforementioned SIMS and includes not only nitrogen that forms a solid solution in the silicon ribbon but also nitrogen that is present in the form of nitride such as Si₃N₄. However, when the growth rate of the silicon ribbon is high, it is conceivable that the segregation effect does not develop so much and nitrogen forms a solid solution in the crystals more efficiently and is taken in at a concentration exceeding a limit of solid solubility. Here, the temperature of crucible 22 during growth of the silicon ribbon and/or the conditions for immersing the surface of substrate 14 for silicon ribbon growth into nitrogen-containing silicon melt 12 were changed and a silicon ribbon whose growth rate was 20 μm/sec to 300 μm/sec was fabricated and evaluated similarly. However, a result similar to that in FIG. 8 was obtained.

### Solar Cell in Example 2

Using the pieces of spherical silicon having various nitrogen concentrations, which were fabricated in Example 2 described above, solar cells including the pieces of spherical silicon having different nitrogen concentrations and having the structure shown in FIG. 6 were fabricated as described below.

First, a plurality of pieces of p-type spherical silicon 53 fabricated in Example 2 were prepared, and phosphorus was diffused onto the outer surfaces of these pieces of p-type spherical silicon 53. N+ layer 61 was thus formed.

Next, spherical silicon 53 having n+ layer 61 formed thereon was placed in the hole of perforated conductive sheet 64 made of an aluminum foil, and n+ layer 61 exposed from the hole of conductive sheet 64 to the rear surface side was removed by etching.

Next, insulating layer 65 made of polyimide was formed on the rear surface of conductive sheet 64, and thereafter, a part of insulating layer 65 was removed to expose the surface of p-type spherical silicon 53. Then, conductive sheet 66 made of an aluminum foil was placed on the exposed surface of spherical silicon 53.

Next, antireflective film 62 made of titanium oxide was formed on the surface of n+ layer 61 on the surface side of conductive sheet 64, and thereafter, antireflective film 62 and conductive sheet 64 were covered with transparent protective film 63 formed of a transparent plastic film. The solar cell in Example 2 was thus fabricated.

The aforementioned solar cell fabrication process was performed for the respective pieces of spherical silicon in Example 2 having different nitrogen concentrations. A plurality of solar cells in Example 2 including the pieces of spherical silicon having different nitrogen concentrations were thus fabricated.

Then, about the respective solar cells in Example 2 fabricated as described above, the reverse leakage current under dark conditions was measured. The result is shown in FIG. 9. In FIG. 9, the horizontal axis indicates the nitrogen concentration (atoms/cm³) of the silicon ribbons in the solar cells in Example 2, and the vertical axis indicates the reverse leakage current (A) under dark conditions. The reverse leakage current under dark conditions was obtained by applying a positive voltage of +10 V to the conductive sheet 64 side of the solar cell and measuring a current flowing through the solar cell, without irradiating the solar cell in Example 2 with light.

As shown in FIG. 9, the following was recognized: when the nitrogen concentration of the spherical silicon is in the range of 5×10¹⁵ atoms/cm³ or higher and 5×10¹⁷ atoms/cm³ or lower, the reverse leakage current under dark conditions tends to be small, and when the nitrogen concentration of the spherical silicon is in the range of 1×10¹⁶ atoms/cm³ or higher and 5×10¹⁶ atoms/cm³ or lower, the reverse leakage current under dark conditions tends to be particularly small.

### Solar Cell in Example 3

Using the silicon ribbons having various nitrogen concentrations, which were fabricated in Example 3 described above, solar cells in Example 3 including the silicon ribbons having different nitrogen concentrations were fabricated similarly to Example 1.

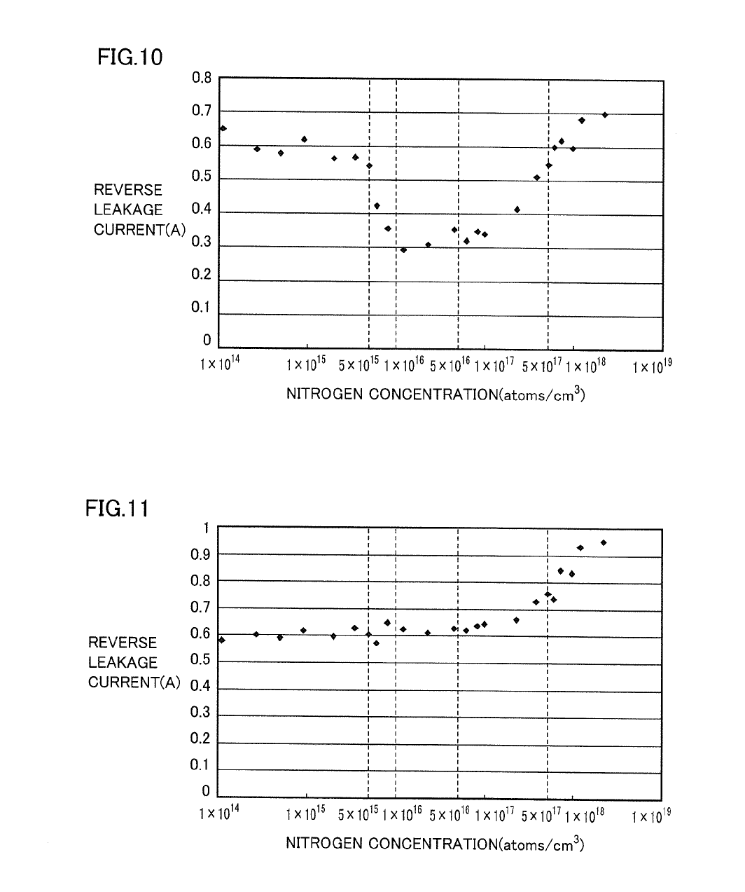

Then, about the respective solar cells in Example 3, the reverse leakage current under dark conditions was measured similarly to Example 1. The result is shown in FIG. 10. In FIG. 10, the horizontal axis indicates the nitrogen concentration (atoms/cm³) of the silicon ribbons in the solar cells in Example 3, and the vertical axis indicates the reverse leakage current (A) under dark conditions. The reverse leakage current under dark conditions was obtained by applying a positive voltage of +10 V to the silver electrode 36 side of the solar cell and measuring a current flowing through the solar cell, without irradiating the solar cell in Example 3 with light.

As shown in FIG. 10, the following was recognized: when the nitrogen concentration of the silicon ribbon is in the range of 5×10¹⁵ atoms/cm³ or higher and 5×10¹⁷ atoms/cm³ or lower, the reverse leakage current under dark conditions tends to be small, and when the nitrogen concentration of the silicon ribbon is in the range of 1×10¹⁶ atoms/cm³ or higher and 5×10¹⁶ atoms/cm³ or lower, the reverse leakage current under dark conditions tends to be particularly small.

### Solar Cell in Comparative Example 1

Using the silicon crystal substrates fabricated by cutting the pieces of cast silicon having various nitrogen concentrations, which were fabricated in Comparative Example 1 described above, to have the same size as that of the silicon ribbons in Example 1, solar cells in Comparative Example 1 including the silicon crystal substrates having different nitrogen concentrations were fabricated similarly to Example 1.

Then, about the respective solar cells in Comparative Example 1, the reverse leakage current under dark conditions was measured similarly to Example 1. The result is shown in FIG. 11. In FIG. 11, the horizontal axis indicates the nitrogen concentration (atoms/cm³) of the silicon ribbons in the solar cells in Comparative Example 1, and the vertical axis indicates the reverse leakage current (A) under dark conditions. The reverse leakage current under dark conditions was obtained by applying a positive voltage of +10 V to the silver electrode 36 side of the solar cell and measuring a current flowing through the solar cell, without irradiating the solar cell in Comparative Example 1 with light.

As shown in FIG. 11, in the solar cell in Comparative Example 1, the reverse leakage current under dark conditions increases as the nitrogen concentration of the silicon crystal substrate increases, and unlike Examples 1 to 3, there is no nitrogen concentration range in which the reverse leakage current under dark conditions decreases locally.

It should be understood that the embodiments disclosed herein are illustrative and not limitative in any respect. The scope of the present invention is defined by the terms of the claims, rather than the description above, and is intended to include any modifications within the scope and meaning equivalent to the terms of the claims.

### INDUSTRIAL APPLICABILITY

The present invention can be used in a silicon ribbon, spherical silicon, a solar cell, a solar cell module, a method for manufacturing the silicon ribbon, and a method for manufacturing the spherical silicon.

### REFERENCE SIGNS LIST

11 silicon ribbon; 12 nitrogen-containing silicon melt; 13 plate-like body; 14 substrate for silicon ribbon growth; 15 arrow; 21 heating heater; 22 crucible; 26 crucible platform; 27 heat insulator; 28 crucible elevating platform; 29 shaft; 31 PSG liquid; 31a PSG film; 32 n+ layer; 33 antireflective film; 34 aluminum paste; 34a aluminum electrode; 35 p+ layer; 36 silver electrode; 36a silver paste; 41 transparent substrate; 42 sealant; 43 protective sheet; 44 conductive member; 51 chamber; 52 heating heater; 53 spherical silicon; 54 container; 55 crucible; 61 n+ layer; 62 antireflective film; 63 transparent protective film; 64, 66 conductive sheet; 65 insulating layer; 71 heating heater; 72 cast silicon; 73 crucible

1. A silicon ribbon (11) directly fabricated from a melt (12), wherein
a nitrogen concentration of said silicon ribbon (11) is 5×10¹⁵ atoms/cm³ or higher and 5×10¹⁷ atoms/cm³ or lower.

2. The silicon ribbon (11) according to claim 1, wherein
said nitrogen concentration is 1×10¹⁶ atoms/cm³ or higher and 5×10¹⁶ atoms/cm³ or lower.

3. A solar cell fabricated using the silicon ribbon (11) as recited in claim 1 or 2.

4. A solar cell module including the solar cell as recited in claim 3.

5. Spherical silicon (53) directly fabricated from a melt (12), wherein
a nitrogen concentration of said spherical silicon (53) is 5×10¹⁵ atoms/cm³ or higher and 5×10¹⁷ atoms/cm³ or lower.

6. The spherical silicon (53) according to claim 5, wherein
said nitrogen concentration is 1×10¹⁶ atoms/cm³ or higher and 5×10¹⁶ atoms/cm³ or lower.

7. A solar cell fabricated using the spherical silicon (53) as recited in claim 5 or 6.

8. A solar cell module including the solar cell as recited in claim 7.

9. A method for manufacturing a silicon ribbon (11), comprising the steps of:
fabricating a nitrogen-containing silicon melt (12); and
growing, from said nitrogen-containing silicon melt (12), a silicon ribbon (11) having a nitrogen concentration of 5×10¹⁵ atoms/cm³ or higher and 5×10¹⁷ atoms/cm³ or lower.

10. The method for manufacturing a silicon ribbon (11) according to claim 9, wherein
in said step of growing a silicon ribbon (11), a silicon ribbon (11) having said nitrogen concentration of 1×10¹⁶ atoms/cm³ or higher and 5×10¹⁶ atoms/cm³ or lower is grown.

11. The method for manufacturing a silicon ribbon (11) according to claim 9 or 10, wherein
in said step of growing a silicon ribbon (11), said silicon ribbon (11) is grown on a substrate (14) for growth.

12. The method for manufacturing a silicon ribbon (11) according to claim 11, wherein
in said step of growing a silicon ribbon (11), a growth rate of said silicon ribbon (11) is 20 μm/sec or higher.

13. A method for manufacturing spherical silicon (53), comprising the steps of:
fabricating a nitrogen-containing silicon melt (12); and
growing spherical silicon (53) having a nitrogen concentration of 5×10¹⁵ atoms/cm³ or higher and 5×10¹⁷ atoms/cm³ or lower, by dropping said nitrogen-containing silicon melt (12).

14. The method for manufacturing spherical silicon (53) according to claim 13, wherein
in said step of growing spherical silicon (53), spherical silicon (53) having said nitrogen concentration of 1×10¹⁶ atoms/cm³ or higher and 5×10¹⁶ atoms/cm³ or lower is grown.

15. The method for manufacturing spherical silicon (53) according to claim 13 or 14, wherein
in said step of growing spherical silicon (53), a growth rate of said spherical silicon (53) is 20 μm/sec or higher.
